(19) United States
(12) Patent Application Publication
(10) Pub. No.: US 2026/0347670 A1
(43) Pub. Date: Nov. 5, 2026

(54) Water-Based Semiconductive Adhesive Bonding Paint Using Carbon Nanotubes

(71) Applicant: ABB Schweiz AG, Baden (CH)

(72) Inventors: Adrienne Novack, Flanders, NJ (US); William Longcor, Newton, NJ (US)

(73) Assignee: ABB Schweiz AG, Baden (CH)

(21) Appl. No.: 19/666,649

(22) Filed: May 4, 2026

Related U.S. Application Data
(60) Provisional application No. 63/798,907, filed on May 2, 2025.

(51) Int. Cl. C09J 9/02; C08K 3/04; C09J 11/04; H05K 9/00

(52) U.S. Cl. CPC C09J 9/02; C08K 3/042; C09J 11/04; H05K 9/0079; C08K 2201/001; C08K 2201/004

(57) ABSTRACT

A water-based semiconductive adhesive bonding paint includes a water-based adhesive bonding paint; and an aqueous suspension comprising carbon nanotubes dispersed in the water-based adhesive bonding paint; wherein the water-based semiconductive adhesive bonding paint is configured to provide adhesive bonding and semiconductive electrical conductivity.

### FIELD OF THE DISCLOSURE

The instant application claims priority to U.S. Provisional Application Ser. No. 63/798,907, filed May 2, 2025, which is incorporated herein in its entirety by reference.

### FIELD OF THE DISCLOSURE

The present disclosure generally relates to surface coverings and, more specifically, to adhesive bonding paint formulations.

### BACKGROUND OF THE DISCLOSURE

Conductive paint additives, primarily using carbon black or metal oxides, are engineered to provide electrical conductivity, antistatic properties, or electromagnetic shielding to surfaces. Carbon black is the most common and cost-effective choice for creating conductive networks within paint, while metal oxides (like tin oxide or conductive mica) are used when specific performance criteria, such as color, transparency, or improved durability, are needed.

Carbon black is a widely used conductive paint additive, and generally includes finely divided, amorphous carbon particles having a high surface area and an aggregate structure that facilitates formation of conductive pathways, when used, for example, within a polymeric binder. In paints and coatings, carbon black may be used to impart electrical conductivity or electrostatic dissipation and, additionally, to provide pigmentation (typically black). Carbon black can achieve targeted conductivity at relatively low loadings and at relatively low cost; however, it may significantly darken the coating, increase viscosity, and present dispersion and surface-finish challenges if not properly formulated. Carbon black–based coatings are commonly used to control electrostatic discharge (ESD control), antistatic flooring, primers for electrostatic spray application, electromagnetic interference (EMI) shielding, and the like.

Metal oxide additives (e.g., antimony-doped tin oxide (ATO), indium tin oxide (ITO), fluorine-doped tin oxide (FTO), and zinc oxide–based systems) provide an alternative approach to imparting conductivity. Such materials are typically semi-conductive ceramic particles supplied as powders or dispersions. A key advantage of metal oxides is that they may provide antistatic or conductive performance while remaining light-colored or substantially transparent, which is generally not achievable with carbon black. Metal oxides may also exhibit high thermal and chemical stability, and their conductivity can be comparatively less sensitive to humidity. However, metal oxides often require higher concentrations than carbon black to achieve comparable conductivity and may be significantly more expensive, which can impact overall formulation cost and, in some cases, mechanical properties.

In practice, carbon black is often selected where coating color is not critical and cost-effective, robust conductivity is desired. Metal oxide additives are often selected where a light-colored or transparent appearance is preferred and/or where long-term stability and controlled surface resistivity are important (e.g., architectural glass coatings, display components, and cleanroom environments).

### BRIEF SUMMARY OF THE INVENTION

The present disclosure generally describes water-based, semi-conductive adhesive bonding paint formulations that combine adhesion performance with electrical conductivity (e.g., semi-conductivity) in a water-based paint system. Such paints may be used for static dissipation and anti-corona applications in high-voltage equipment, including large motors and turbine generators, to normalize electrical stresses and reduce or prevent corona discharge. Such coatings may also be used to dissipate static in electronic assemblies, to provide electromagnetic and radio-frequency interference (EMI/RFI) shielding, to reduce the impact of unwanted signals on sensitive electronic components, and to facilitate grounding by enabling controlled dissipation of static electricity, and the like.

More specifically, the present disclosure is directed to a water-based semi-conductive adhesive bonding paint created by adding a water-based suspension of carbon nanotubes to a water-based adhesive bonding paint. In one example, Tuball^{TM} COAT_E H2O and Tuball^{TM} BATT H2O aqueous nanotube suspensions were used in various ratios in mixture with Cilbond® R-7290W base paint to develop various embodiments of water-based semi-conductive adhesive bonding paint. This is a sustainable material due to it being water-based instead of solvent-based and due to the use of carbon nanotubes as the conductive additive instead of carbon black, the current industry standard for conductive additives.

### DETAILED DESCRIPTION OF THE INVENTION

Existing conductive and antistatic coating systems may provide electrical functionality to a painted surface, but can present formulation tradeoffs when adhesive bonding, semiconductive performance, and water-based processing are all desired in the same material. Conductive additives such as carbon black or metal oxides can affect color, viscosity, dispersion, surface finish, cost, or mechanical properties, and antistatic bonding paints may not provide the level of conductivity desired for applications that use controlled dissipation of electrical charge. Accordingly, there remains a technical need for a water-based adhesive bonding paint that can provide semiconductive electrical behavior while retaining suitable bonding capability for substrates such as metal, fiberglass, and EPDM rubber.

The disclosed technology addresses this need by dispersing carbon nanotubes into a water-based adhesive bonding paint through mixing the paint with an aqueous nanotube suspension. In some embodiments, a water-based bonding agent formulated for rubber-to-metal applications is combined with an aqueous suspension containing single-walled carbon nanotubes or graphene nanotubes at a selected ratio, such that the resulting paint provides both adhesive bonding and semiconductive conductivity. The nanotube additive may form conductive pathways at relatively low additive concentrations, while the water-based carrier maintains a water-based formulation and can reduce reliance on solvent-based materials or higher loadings of conventional conductive additives.

The ratio of the water-based adhesive bonding paint to the aqueous nanotube suspension may be selected to balance bonding performance, surface resistivity, processability, and dilution effects. For example, ratios within a range from 50:50 to 95:5, including formulations using aqueous nanotube suspensions containing 0.4% or 0.8% carbon nanotubes, may be used to produce a semiconductive adhesive bonding paint suitable for bonding EPDM rubber to metal or fiberglass and for applications involving static dissipation, electrical stress normalization, corona reduction, or electromagnetic and radio-frequency interference shielding.

In the present disclosure, a water-based semi-conductive bonding paint such as Cilbond® R-7290W was used as a base. In one embodiment, an 80:20 ratio of Cilbond® R-7290W to Tuball^{TM} COAT_E H2O and a ratio of 85:15 Cilbond® R-7290W to Tuball^{TM} BATT H2O were used to create the desired surface covering. Other ratios can also be used. For example, the ratio of base paint to aqueous dispersion of nanotubes can range anywhere between 50:50 to 95:5. The resulting surface covering, which is the desired water-based semi-conductive adhesive bonding paint that contains nanotubes has satisfactory bonding capabilities and the needed conductivity for various applications. It is also water-based, which furthers sustainability. The amount of additive material, in this case, nanotubes, is lower than the typical concentration or amount of conducive additives that would have been needed if carbon black or a metal oxide had been used instead.

This new material is a water-based, semi-conductive adhesive bonding paint used to bond metal and fiberglass to EPDM rubber using Cilbond® R-7290W as a base. The aqueous suspensions of nanotubes, Tuball^{TM} COAT_E, has 0.4% carbon nanotubes, and Tuball^{TM} BATT, has 0.8% carbon nanotubes suspended in water. Since the carbon nanotubes are small enough (they are nanomaterials), they do not interfere with the bonding nature of the materials in the Cilbond® paint. Adding too much Tuball^{TM} also presents a risk for over-dilution due to the amount of water in the suspension.

Various samples, beginning with 100:0 to have a control sample and also testing 95:5, 90:10, 85:15, and 80:20 with mixtures of Cilbond® R-7290W: Tuball^{TM} COAT_E and Cilbond® R-7290W: Tuball^{TM} BATT were tested using adhesive bonding test methods and surface resistivity test methods. Adding in the Tuball caused the texture and consistency of the base paint to change and become similar to that of a mousse or a pudding.

For mixing the materials together, including any needed dilutions for easier processing and application, specialized mixing techniques were used.

In the present disclosure, Cilbond® R-7290W was used as a base paint, but any other a high-performance, one-component, water-based bonding agent formulated for rubber-to-metal applications can be used.

In the present disclosure, the Tuball ™ nanotubes that were used in aqueous suspension are exemplary – any other graphene nanotubes in suspension can also be used that are graphene nanotubes having a one-atom-thick graphene sheet shaped as a tube more than 5 µm long.

In one general aspect, the present disclosure is directed to a water-based semi-conductive adhesive bonding paint that includes a pre-determined concentration of carbon or graphene nanotubes, which have been dispersed in the base paint in the form of mixing of the base paint with an aqueous solution containing the nanotubes.

In a first embodiment, the present disclosure describes a water-based semiconductive adhesive bonding paint that includes a water-based adhesive bonding paint; and an aqueous suspension comprising carbon nanotubes dispersed in the water-based adhesive bonding paint, wherein the water-based semiconductive adhesive bonding paint is configured to provide adhesive bonding and semiconductive electrical conductivity.

In one embodiment, the water-based adhesive bonding paint comprises a high-performance, one-component, water-based bonding agent formulated for bonding to metal, fiberglass, and/or rubber, such as Cilbond® R-7290W, but other bonding agents may be used.

In one embodiment, the carbon nanotubes comprise graphene nanotubes are formed from a one-atom-thick graphene sheet shaped as a tube more than 5 µm long. The carbon nanotubes may be embodied as single-walled carbon nanotubes suspended in water.

In one embodiment, a ratio of the water-based adhesive bonding paint to the aqueous suspension is selected such that the aqueous suspension does not over-dilute the was-based adhesive boding paint.

In one embodiment, when the aqueous suspension contains 0.4% carbon nanotubes, ratio of the water-based adhesive bonding paint to the aqueous suspension is 80:20.

In one embodiment, when the aqueous suspension contains 0.8% carbon nanotubes, the ratio of the water-based adhesive bonding paint to the aqueous suspension is 85:15.

In general, a ratio of the water-based adhesive bonding paint to the aqueous suspension is within a range from 50:50 to 95:5.

In a desired effect of the disclosure, the water-based semiconductive adhesive bonding paint is configured to normalize electrical stresses, and/or reduce corona discharge in high-voltage equipment.

In another aspect, the disclosure describes a method for coating a surface, the method comprising applying a water-based semiconductive adhesive bonding paint to the surface, wherein the water-based semiconductive adhesive bonding paint comprises a water-based adhesive bonding paint and an aqueous suspension comprising carbon nanotubes dispersed in the water-based adhesive bonding paint.

In one embodiment, the surface comprises one or more of rubber, metal, and fiberglass. The water-based semiconductive adhesive bonding paint may provide controlled dissipation of static electricity, and/or electromagnetic and radio-frequency interference shielding.

In one embodiment, the water-based semiconductive adhesive bonding paint is formulated by providing the water-based adhesive bonding paint and mixing therein the aqueous suspension comprising carbon nanotubes dispersed in the water-based adhesive bonding paint.

In another aspect, the disclosure describes a method for preparing a water-based semiconductive adhesive bonding paint, the method comprising mixing a water-based adhesive bonding paint with an aqueous suspension comprising carbon nanotubes; and dispersing the carbon nanotubes in the water-based adhesive bonding paint to form the water-based semiconductive adhesive bonding paint.

In one embodiment, mixing the water-based adhesive bonding paint with the aqueous suspension comprises mixing the water-based adhesive bonding paint and the aqueous suspension at a ratio from 50:50 to 95:5. The method may further include selecting a ratio of the water-based adhesive bonding paint to the aqueous suspension based on adhesive bonding testing and surface resistivity testing, and/or diluting the water-based adhesive bonding paint and the aqueous suspension during mixing to facilitate processing and application.

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and “at least one” and similar referents in the context of describing the invention (especially in the context of the following claims) are to be construed to cover both the singular and the plural, unless otherwise indicated herein or clearly contradicted by context. The use of the term “at least one” followed by a list of one or more items (for example, “at least one of A and B”) is to be construed to mean one item selected from the listed items (A or B) or any combination of two or more of the listed items (A and B), unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

What is claimed is:

1. A water-based semiconductive adhesive bonding paint, comprising:
a water-based adhesive bonding paint; and
an aqueous suspension comprising carbon nanotubes dispersed in the water-based adhesive bonding paint;
wherein the water-based semiconductive adhesive bonding paint is configured to provide adhesive bonding and semiconductive electrical conductivity.

2. The water-based semiconductive adhesive bonding paint of claim 1, wherein the water-based adhesive bonding paint comprises a high-performance, one-component, water-based bonding agent formulated for bonding to metal, fiberglass, and/or rubber.

3. The water-based semiconductive adhesive bonding paint of claim 1, wherein the water-based adhesive bonding paint comprises Cilbond® R-7290W.

4. The water-based semiconductive adhesive bonding paint of claim 1, wherein the carbon nanotubes comprise graphene nanotubes formed from a one-atom-thick graphene sheet shaped as a tube more than 5 µm long.

5. The water-based semiconductive adhesive bonding paint of claim 1, wherein the carbon nanotubes comprise single-walled carbon nanotubes suspended in water.

6. The water-based semiconductive adhesive bonding paint of claim 1, wherein a ratio of the water-based adhesive bonding paint to the aqueous suspension is from 50:50 to 95:5.

7. The water-based semiconductive adhesive bonding paint of claim 1, wherein the aqueous suspension contains 0.4% carbon nanotubes and a ratio of the water-based adhesive bonding paint to the aqueous suspension is 80:20.

8. The water-based semiconductive adhesive bonding paint of claim 1, wherein the aqueous suspension contains 0.8% carbon nanotubes and a ratio of the water-based adhesive bonding paint to the aqueous suspension is 85:15.

9. The water-based semiconductive adhesive bonding paint of claim 1, wherein a ratio of the water-based adhesive bonding paint to the aqueous suspension is selected such that the aqueous suspension does not over-dilute the was-based adhesive boding paint.

10. The water-based semiconductive adhesive bonding paint of claim 1, wherein the water-based semiconductive adhesive bonding paint is configured to normalize electrical stresses.

11. The water-based semiconductive adhesive bonding paint of claim 1, wherein the water-based semiconductive adhesive bonding paint is configured to reduce corona discharge in high-voltage equipment.

12. A method for coating a surface, the method comprising:
applying a water-based semiconductive adhesive bonding paint to the surface,
wherein the water-based semiconductive adhesive bonding paint comprises a water-based adhesive bonding paint and an aqueous suspension comprising carbon nanotubes dispersed in the water-based adhesive bonding paint.

13. The method of claim 12, wherein the surface comprises one or more of rubber, metal, and fiberglass.

14. The method of claim 12, further comprising using the water-based semiconductive adhesive bonding paint to provide controlled dissipation of static electricity.

15. The method of claim 12, further comprising using the water-based semiconductive adhesive bonding paint to provide electromagnetic and radio-frequency interference shielding.

16. The method of claim 12, wherein the water-based semiconductive adhesive bonding paint is formulated by providing the water-based adhesive bonding paint and
mixing therein the aqueous suspension comprising carbon nanotubes dispersed in the water-based adhesive bonding paint.

17. A method for preparing a water-based semiconductive adhesive bonding paint, the method, comprising:
mixing a water-based adhesive bonding paint with an aqueous suspension comprising carbon nanotubes; and
dispersing the carbon nanotubes in the water-based adhesive bonding paint to form the water-based semiconductive adhesive bonding paint.

18. The method of claim 17, wherein mixing the water-based adhesive bonding paint with the aqueous suspension comprises mixing the water-based adhesive bonding paint and the aqueous suspension at a ratio from 50:50 to 95:5.

19. The method of claim 17, further comprising selecting a ratio of the water-based adhesive bonding paint to the aqueous suspension based on adhesive bonding testing and surface resistivity testing.

20. The method of claim 17, further comprising diluting the water-based adhesive bonding paint and the aqueous suspension during mixing to facilitate processing and application.
